(19) United States
(12) Patent Application Publication
(10) Pub. No.: US 2009/0126779 A1
(43) Pub. Date: May 21, 2009

(54) PHOTOVOLTAIC DEVICES IN TANDEM ARCHITECTURE

(75) Inventors: Alan J. HEEGER, Santa Barbara, CA (US); Kwanghee LEE, Goleta, CA (US); Jin Young KIM, Goleta, CA (US)

Correspondence Address: MORRISON & FOERSTER LLP, 755 PAGE MILL RD, PALO ALTO, CA, 94304-1018, US

(73) Assignee: The Regents of the University of California

(21) Appl. No.: 11/766,768

(22) Filed: Jun. 21, 2007

Related U.S. Application Data
(60) Provisional application No. 60/844,746, filed on Sep. 14, 2006.

(51) Int. Cl. H01L 31/042; H01L 51/30

(52) U.S. Cl. 136/249; 438/82; 257/E51.026; 977/734

(57) ABSTRACT

A tandem photovoltaic device includes a first cell and a second cell arranged in tandem. The first cell is configured to receive incident electromagnetic radiation and includes a first charge separating layer having a first semiconducting polymer adapted to create electric charge carriers generated by electromagnetic radiation. A second cell is configured to receive electromagnetic radiation passing out of the first cell in a light propagation path. The second cell includes a second charge separating layer having a second semiconducting polymer adapted to create electric charge carriers generated by electromagnetic radiation. A first titanium oxide layer is interposed between the first and second cells, wherein the first titanium oxide layer is substantially amorphous and has a general formula of TiOx where X being a number of 1 to 1.96.

### CROSS-REFERENCE TO RELATED APPLICATIONS

This application claims the benefit of priority under 35 USC § 119(e) to U.S. Provisional Application Ser. No. 60/844,746 filed Sep. 14, 2006, the disclosure of which is incorporated herein by reference in its entirety.

### STATEMENT REGARDING GOVERNMENT SUPPORT

This invention was made in part during the course of work under grant numbers DE-FG02-06ER46324 from the United States Department of Energy. The United States Government has certain right in this invention.

### BACKGROUND

This invention relates in general to polymer-based electronic devices and in particular to high efficient polymer photovoltaic devices in tandem architecture.

Polymer photovoltaic devices offer special opportunities as renewable energy sources since they can be fabricated in large areas using low cost printing and coating technologies that can simultaneously pattern active materials on light-weight flexible substrates. However, the limited power-conversion efficiency (ηₑ) of prior art polymer photovoltaic devices has hindered the path toward commercialization, even though an encouraging power-conversion efficiency of 5% has been reported.

Photovoltaic devices in tandem architecture, a multilayer structure that includes two or more photovoltaic cells in series, offer a number of advantages. Because the two cells are in series, the open circuit voltage (V_{OC}) is increased to the sum of the V_{OC} of the individual cells. In addition, the use of two photoactive layers with different band gaps enables absorption over a broad range of photon energies within the solar emission spectrum. Typically, a wide band gap semiconductor is used for the first or front cell and a narrow band gap semiconductor for the second or back cell in a tandem photovoltaic device. Since the electron-hole pairs generated by photons with energies greater than the energy gap rapidly relax to the respective band edges, the power conversion efficiency of the two cells in series is inherently better than that of the individual cell made from the smaller band gap material. Moreover, because of the low mobility of the charge carriers in charge separation layers such as polymer-fullerene composites, an increase in the thickness of the active layer increases the internal resistance of the device, which reduces both the V_{OC} and fill factor (FF). Thus, the tandem architecture can have a higher optical density over a wider fraction of the solar emission spectrum than a single cell without increasing the internal resistance. The tandem architecture can therefore improve light harvesting in polymer based photovoltaic devices.

Tandem structures have been investigated for small molecule heterojunction organic solar cells and for hybrid organic solar cells in which the first cell utilizes an evaporated small molecule material and the second cell uses a conjugated polymer. The two cells are separated by a semitransparent metal layer. Recently, polymer-fullerene composite tandem photovoltaic devices were reported. In these devices, a thermally evaporated metal layer is used as a charge-recombination layer and as a protection layer to prevent interlayer mixing during the spin-casting of the second cell. These polymer-based tandem photovoltaic devices exhibit a high open circuit voltage V_{OC}, close to the expected sum of the open circuit voltages from the two individual cells, but the short circuit current density J_{SC} is lower than that of either single cells. This is because when same polymers are used for both the front and the back cells as in prior art devices, the absorption spectra of the polymers are identical, but the back cell absorbs less incident light and thus generates lower photocurrent. Because the two cells are in series, the current through the multilayer device is determined by that from the back cell. Moreover, since the interfacial metal layer is only semitransparent, the additional absorption also reduces the intensity of the light incident on the back cell. Thus, even when two different polymers are used, the photocurrent is correspondingly reduced.

Tandem photovoltaic devices have been described in U.S. Pat. Nos. 4,255,211; 6,198,091; 6,278,055; 6,297,495; 6,352,777; 6,440,769; 6,657,378; and United States Patent Publication No. 2002/0189666.

### SUMMARY

In one aspect is provided a tandem photovoltaic device comprising a first cell, a second cell, and a first titanium oxide layer interposed between the first and second cells. The first cell is configured to receive incident electromagnetic radiation and comprises a first charge separating layer having a first semiconducting polymer adapted to create electric charge carriers generated by electromagnetic radiation. The second cell is configured to receive electromagnetic radiation passing out of the first cell in a light propagation path and comprises a second charge separating layer having a second semiconducting polymer adapted to create electric charge carriers generated by electromagnetic radiation. The first titanium oxide layer is substantially amorphous and has a general formula of TiOₓ where X represents a number of 1 to 1.96.

In another aspect, a method of preparing a tandem photovoltaic device is provided. The method includes applying a solution comprising a first semiconducting polymer and a first fullerene derivative to form a first charge separating layer, applying a solution comprising a titanium oxide precursor to form a first substantially amorphous titanium oxide layer, and applying a solution comprising a second semiconducting polymer and a second fullerene derivative to form a second charge separating layer.

### BRIEF DESCRIPTION OF THE DRAWINGS

These and various other features and advantages of the present invention will become better understood upon reading of the following detailed description in conjunction with the accompanying drawings and the appended claims provided below, where:

FIG. 1 schematically illustrates a tandem photovoltaic device in accordance with one embodiment of the invention;

FIG. 2 shows the absorption spectra of films poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”), poly-(3-hexylthiophene) (“P3HT”), ([6,6]-phenyl-C₆₁-buteric acid methyl ester) (“PCBM”), and [6,6]-phenyl-C₇₁butyric acid methyl ester (“PC₇₀BM”).

FIG. 3 shows the absorption spectra of PCPDTBT:PCBM composite film, P3HT:PC₇₀BM composite film, and PCPDTBT:PCBM/P3HT:PC₇₀BM bilayer film;

FIG. 4 illustrates the structure of a tandem photovoltaic device in accordance with one embodiment of the invention. On the left of FIG. 4 are cross section images of the device in transmission electron microscopy (“TEM”). The scale bar is 100 nm in the lower TEM image and 20 nm in the upper TEM image;

FIG. 5 is an energy level diagram illustrating the highest occupied molecular orbital (HOMO) energies and the lowest unoccupied molecular orbital (LUMO) energies of each of the component materials for the photovoltaic device as illustrated in FIG. 4;

FIG. 6 shows the incident photon-to-current collection efficiency (IPCE) spectra of single cells and a tandem photovoltaic device having the structure as illustrated in FIG. 4 in accordance with one embodiment of the invention;

FIG. 7 shows current density v. voltage (J-V) characteristics of single cells and a tandem photovoltaic device having the structure as illustrated in FIG. 4 in accordance with one embodiment of the invention;

FIG. 8 shows J-V characteristics of a tandem photovoltaic device having the structure as illustrated in FIG. 4 measured with different incident light intensities from 0 mW/cm² to 200 mW/cm² (AM1.5G solar spectrum);

FIG. 9 shows short circuit current density (J_{SC}), open circuit voltage (V_{OC}, fill factor (FF), and power conversion efficiency (ηₑ) plotted as functions of incident light intensities of a tandem photovoltaic device having the structured as illustrated in FIG. 4;

FIG. 10A illustrates the structure of a single photovoltaic cell in accordance with one embodiment of the invention;

FIG. 10B shows J-V characteristics of the single photovoltaic cell as illustrated in FIG. 10A;

FIG. 11A illustrates the structure of a tandem photovoltaic device in accordance with one embodiment of the invention;

FIG. 11B illustrates J-V characteristics of a tandem photovoltaic device having the structure as illustrated in FIG. 11A;

FIG. 12 illustrates J-V characteristics of tandem photovoltaic devices having the structure as illustrated in FIG. 11A

FIG. 13A illustrates the structure of a tandem photovoltaic device in accordance with one embodiment of the invention;

FIG. 13B shows J-V characteristics of tandem photovoltaic devices having the structure as illustrated in FIG. 13A;

FIG. 14A illustrates the structure of a tandem photovoltaic device in accordance with one embodiment of the invention;

FIG. 14B shows J-V characteristics of a tandem photovoltaic device having the structure as illustrated in FIG. 14A;

FIG. 15 shows J-V characteristics of tandem photovoltaic devices having the structure as illustrated in FIG. 14A;

FIG. 16A is a schematic diagram showing an experimental setup for measuring IPCE of a tandem photovoltaic device; and

FIG. 16B shows IPCE spectra of a tandem photovoltaic device.

### DETAILED DESCRIPTION OF VARIOUS EMBODIMENTS

Various embodiments of the invention are described hereinafter with reference to the figures. It should be noted that some figures are schematic and the figures are only intended to facilitate the description of specific embodiments of the invention. They are not intended as an exhaustive description of the invention or as a limitation on the scope of the invention. In addition, one aspect described in conjunction with a particular embodiment of the present invention is not necessarily limited to that embodiment and can be practiced in any other embodiments of the present invention. For instance, various embodiments are provided in the drawings and the description in connection with photovoltaic devices having two sub-cells. It will be appreciated that the claimed invention may also be used in photovoltaic devices or other electronic devices with a plurality of sub-cells such as three or more sub-cells.

As used herein, the phrase “tandem photovoltaic device” refers to a photovoltaic device that includes two or more sub-cells arranged in tandem.

As used herein, the phrase “front cell or front sub-cell” refers to a cell in a tandem photovoltaic device that receives incoming incident photons, light, or electromagnetic radiation before a back sub-cell in a light propagation path. The term “back cell or back sub-cell” refers to a cell in a photovoltaic device that receives the photons, light or electromagnetic radiation passing out of a front cell in the light propagation path.

As used herein, the phrase “charge separation layer” is used interchangeably with “bulk heterojunction layer” and refers to a photoactive layer which comprises semiconducting materials adapted to absorbed photons, light, or electromagnetic radiation of selected spectral energies to generate electric charge carriers of electrons and holes.

As used herein, the phrase “hole transport layer” refers to a layer that is preferentially hole conducting. As used herein, the phrase “electron transport layer” refers to a layer that is preferentially electron conducting.

As used herein, the term “anode” refers to an electrode in a photovoltaic device to which holes move from the adjacent photoactive layer. As used herein, the term “cathode” refers to an electrode in a photovoltaic device to which electrons move from the adjacent photoactive layer.

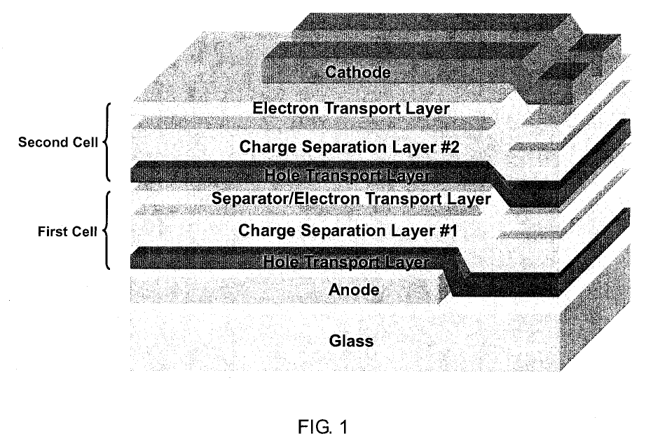

FIG. 1 illustrates an exemplary tandem photovoltaic device in accordance with one embodiment of the invention. In general, the tandem photovoltaic device comprises a substrate supporting a front cell and a back cell arranged in tandem. The front cell may comprise an anode, a hole transport layer, a first charge separation layer, and an electron transport layer. The back cell may comprise a cathode, an electron transport layer, a second charge separation layer, and a hole transport layer. Interposed between the front and back cells is a separation layer.

The substrate provides physical support for the photovoltaic device. Preferably, the substrate is made of materials that are substantially transparent so that light enters the front cell through the substrate. As used herein, the phrase “substantially transparent” means allowing at least 70 percent and preferably at least 80 percent transmission of light having wavelengths ranging from the infrared to visible and ultraviolet regions of the solar spectrum. The terms “photon” and “light” are used interchangeably to mean electromagnetic radiation having wavelength in the range from about 290 nanometer to about 2500 nanometer.

Exemplary materials from which substrate can be formed include glass, quartz and suitable polymers such as polyethylene terephthalates, polyimides, polyethylene naphthalates, polymeric hydrocarbons, cellulosic polymers, polycarbonates, polyamides, polyethers, polyether ketones, and derivatives thereof including copolymers of such materials. In some embodiments, combinations of polymeric materials are used. In some embodiments, different regions of substrate can be formed of different materials.

The substrate can be flexible, semi-rigid or rigid. In some embodiments, the substrate has a flexural modulus of less than about 5,000 mega Pascals. In some embodiments, different regions of substrate can be flexible, semi-rigid or inflexible (e.g., one or more regions flexible and one or more different regions semi-rigid, one or more regions flexible and one or more different regions inflexible).

The thickness of the substrate can be in the range from about a few microns to about 1,000 microns. In some embodiments, the substrate has a thickness ranging from about 10 microns to about 100 microns.

The anode of the front cell is formed on or adjacent to the substrate. The anode is configured to receive incident light and transmit light into the cells. Therefore, anode is preferably made of materials that are substantially transparent as defined above. The anode may also be configured to collect hole charge carriers from the front cell.

Exemplary materials from which the anode can be made include conductive metal-metal oxide or sulfide materials such as indium-tin oxide (ITO). By way of example, a representative ITO material allows about 80 percent transmission of light at wavelength of 550 nm. Other materials such as gold or silver may also be used.

The anode is commonly deposited on the substrate by thermal vapor deposition, electron beam evaporation, RF or Magnetron sputtering, chemical deposition or other methods known in the art.

The cathode of the back cell is disposed on or adjacent to the back cell. The cathode may be configured to collect electron charge carriers from the back cell. Typically the cathode is made of a metal. By way of example, metal aluminum (Al) can be used to form the cathode. The cathode can be formed by vapor deposition or other methods known in the art. The cathode need not be transparent. Thus, conducting materials such as various forms of silver paste (silver particles dispersed in a solvent), can be used to deposit the cathode. The use of materials such as silver paste enables the deposition of the cathode by printing and coating technologies.

In some embodiments, a hole transport layer can be formed on the anode to provide a “bilayer electrode” in the front cell A hole transport layer may be 20 to 30 nm thick and be cast from a solution onto the anode. Exemplary materials for hole transport layers include semiconducting organic polymers such as poly(3,4-ethylenedioxylenethiophene)-polystyrene sulfonic acid (“PEDOT:PSS”). In some embodiments, a hole transport layer can also be formed in the back cell adjacent to the separation layer. A hole transport layer in the back cell can be 20 to 30 nm thick and semiconducting organic polymers such as PEDOT:PSS can be used.

In some embodiments, an electron transport layer can be formed adjacent to the cathode. An electron transport layer may be 20 to 30 nm thick and be cast from a solution onto the second charge separation layer. Exemplary materials for electron transport layers include titanium dioxide as will be described in more detail below.

The charge separation layers in the front and/or back cells may comprise one or more polymer compositions. For example, the first and/or the second charge separation layer may include a polymer composite that includes a component which serves as an electron donor and a component which serves as an electron acceptor.

By way of example, the charge separation layer may be a heterojunction layer comprising a semiconducting conjugated polymer as an electron donor and a fullerene derivative as an electron acceptor.

Conjugated polymers are characterized in that they have overlapping π orbitals, which contribute to the conductive properties. Conjugated polymers may also be characterized in that they can in principle assume two or more resonance structures. The conjugated polymer may be linear or branched so long as the polymer retains its conjugated nature.

Examples of suitable conjugated organic polymers include one or more of polyacetylene; polyphenylenes; poly-(3-hexylthiophene) (“P3HT”); poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT” or “ZZ50”); polyphenylacetylene; polydiphenylacetylene; polyaniline; poly(p-phenylene vinylene); polythiophene; polyporphyrins; porphyrinic macrocycles, thiol derivatized polyporphyrins polymetallocenes such as polyferrocenes, polyphthalocyanines; polyvinylenes; polyphenylvinylenes; polysilanes; polyisothianaphthalenes; polythienylvinylenes; derivatives of any of these materials and combinations thereof.

Fullerene is a compound including a three-dimensional carbon skeleton having a plurality of carbon atoms. The carbon skeleton of such fullerenes generally forms a closed shell, which may be, e.g., spherical or semi-spherical in shape. Alternatively, the carbon skeleton may form an incompletely closed shell, such as, e.g., a tubular shape. Carbon atoms of fullerenes are generally linked to three nearest neighbors in a tetrahedral network. Fullerenes may be designated as Cₙ where n is an integer related to the number of carbon atoms of the carbon skeleton. For example, C₆₀ defines a truncated icosahedron including 32 faces, of which 12 are pentagonal and 20 are hexagonal.

By way of example, suitable fullerene derivatives include ([6,6]-phenyl-C₆₁-buteric acid methyl ester) (“PCBM”) and [6,6]-phenyl-C₇₁butyric acid methyl ester (“PC₇₀BM”).

Various combinations of conjugated polymers and fullerene derivatives may be used for the first and the second charge separation layers. In some embodiments, the photovoltaic device may comprise a conjugated polymer/fullerene derivative composite having a wide band gap for the charge separation layer of the front cell, and a conjugated polymer/fullerene derivative composite having a narrow band gap for the charge separation layer of the back cell. In some embodiments, the photovoltaic device may comprise a conjugated polymer/fullerene derivative composite having a narrow band gap for the charge separation layer of the front cell, and a conjugated polymer/fullerene derivative composite having a wide band gap for the charge separation layer of the back cell, forming a so called “inverted structure.” As used herein, the phrase “band gap” refers to the energy difference between the top of the valence band and the bottom of the conduction band of a semiconducting material, where electrons are able to jump from one band to another. A semiconducting material having a band gap greater than that of common semiconducting materials such as silicon, germanium, and gallium arsenide is referred to as a wide band gap material. Likewise, a semiconducting material having a band gap smaller than or comparable to that of common semiconducting materials such as silicon, germanium, and gallium arsenide is referred to as a narrow band gap material. By way of example, PCPDTBT is a narrow band gap semiconducting polymer, while P3HT is a wide band gap semiconducting polymer.

By way of example, the charge separation layer may comprise P3HT:PC₇₀BM composite, P3HT:PCBM composite, PCPDTBT:PC₇₀BM composite, and PCPDTBT:PCBM composite. The molecular structure of poly-(3-hexylthiophene) (“P3HT”), poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT” or “ZZ50”), ([6,6]-phenyl-C₆₁-buteric acid methyl ester) (“PCBM”), and [6,6]-phenyl-C₇₁butyric acid methyl ester (“PC₇₀BM”) are as follows:

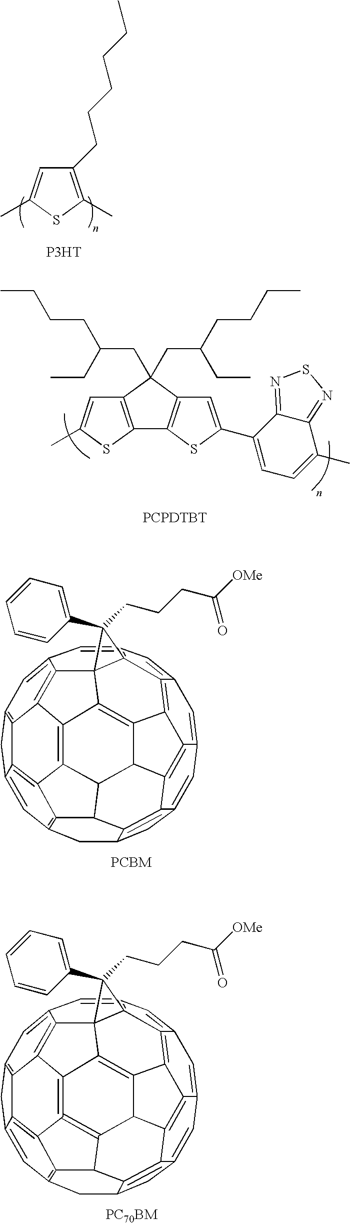

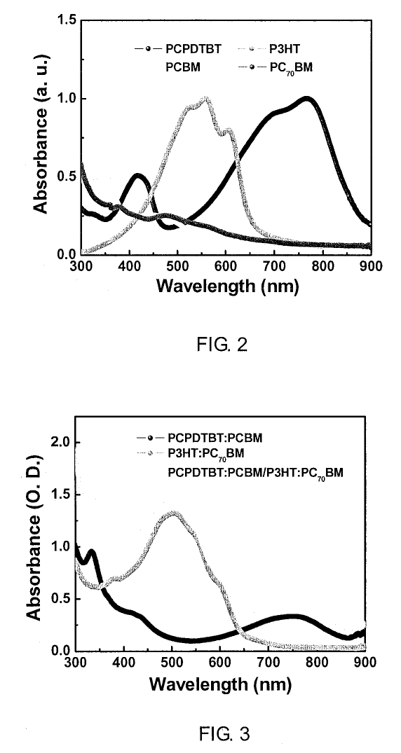

FIG. 2 illustrates the absorption spectrum of each of PCPDTBT, P3HT, PCBM, and PC₇₀BM materials. The absorption bands of P3HT and PCPDTBT complement each other, making these two materials appropriate for use in the two sub-cells of a spectrum splitting tandem photovoltaic device. As used herein, an absorption band is a range of wavelengths (or, equivalently, frequencies) in the electromagnetic spectrum within which electromagnetic energy is absorbed by a polymer.

FIG. 3 illustrates the absorption spectra of exemplary bulk heterojunction composite films of PCPDTBT:PCBM, P3HT:PC₇₀BM, and bilayer film of PCPDTBT:PCBM/P3HT:PC₇₀BM. The absorption of PCPDTBT:PCBM film is relatively weak in the visible spectral range but relatively strong in the near-IR and in the UV ranges. The strong band in the near-IR range between 700 nm and 850 nm arises from the interband π-π* transition of PCPDTBT. The strong band in the UV range arises primarily from the HOMO-LUMO transition of PCBM. The absorption of P3HT:PC₇₀BM film falls in the “hole” in the PCPDTBT:PCBM spectrum and covers the visible spectral range. The electronic absorption spectrum of a tandem photovoltaic device can be described as a simple superposition of the absorption spectra of the two complementary composites.

In some exemplary embodiments, the photovoltaic device comprises PCPDTBT:fullerene derivative (such as PCBM or PC₇₀BM) composite film as the first charge separation layer of the front cell, and P3HT:fullerene derivative composite film as the second charge separation layer of the back cell. In some embodiments, the photovoltaic device comprises P3HT:fullerene derivative composite film as the first charge separation layer of the front cell, and PCPDTBT:fullerene derivative composite film as the second charge separation layer of the back cell.

In one specific embodiment, the photovoltaic device comprises PCPDTBT:PCBM composite film as the first charge separation layer of the front cell, and P3HT:PC₇₀BM composite film as the second charge separation layer of the back cell.

In another specific embodiment, the photovoltaic device comprises PCPDTBT:PC₇₀BM composite film as the first charge separation layer of the front cell, and P3HT:PC₇₀BM composite film as the second charge separation layer of the back cell.

In a further specific embodiment, the photovoltaic device comprises P3HT:PC₇₀BM composite film as the first charge separation layer of the front cell, and PCPDTBT:PC₇₀BM composite film as the second charge separation layer of the back cell.

A separation layer or separator is interposed between the front and back cells. In exemplary embodiments, the separation layer is a substantially amorphous TiOₓ layer having the general formula of TiOₓ, where x represents a number from 1 to 1.96, preferably from 1.1 to 1.9, and more preferably from 1.2 to 1.9. These values represent from 50% to 98% full oxidation, preferably 55% to 95%, and more preferably 60% to 95% full oxidation.

The thickness of the TiOₓ layer can range from 5 to 500 nm, depending on specific applications. In most applications, the thickness can range from 5 to 100 nm. In some applications, good results can be obtained with the thickness ranging from 10 to 50 nm, or from 10 to 40 nm.

The TiOₓ films according to embodiments of the invention can be prepared using a sol-gel processed TiOₓ precursor solution. Atomic force microscope (AFM) scans show that the resulting TiOₓ films are smooth with surface features smaller than a few nanometers. X-ray diffraction data demonstrate that the TiOₓ films are substantially amorphous. The TiOₓ, forms a high quality film on top of the active polymer layer.

While any compatible processing method may be used to apply TiOₓ, layers, solvent processing is preferred. In solvent processing, a layer of a solution or suspension such as a colloidal suspension of one or more TiOₓ precursors is applied. Solvent is removed, most commonly by evaporation to yield a continuous thin layer of TiOₓ, or a TiOₓ precursor which is converted to TiOₓ upon further processing such as mild heating. While the invention is not limited to any theories, it is believed that the precursor converts to TiOₓ, by hydrolysis and condensation processes as follows:

Ti(OR)₄+4H₂O->TiOₓ+YROH.

The TiOₓ, precursor can be a titanium alkoxide such as titanium(IV) butoxide, titanium(IV) chloride, titanium(IV) ethoxide, titanium(IV) methoxide, titanium(IV) propoxide. Other titanium sources such as Ti(SO₄)₂ and so on can also be used. Such materials are commonly available and soluble in lower alkanols such as C₁-C₄ alkanols which are generally compatible with and nondestructive to other organic polymer layers commonly found in microelectronic devices. Alkoxyalkanols such as methoxy-ethanol and the like can also be used. The solvents selected should not react with the TiOₓ precursor. Therefore, care should be taken when aqueous solvents or mixed aqueous/organic solvents are used during processing as the water component can cause premature reaction such as hydrolysis of the TiOₓ precursor. Another factor to be considered in selecting a titanium source and solvent is the ability of the precursor solution to wet the substrate upon which the solution is to be spread. The lower alkanol-based solutions/suspensions described above provide good wetting with organic layers.

The titanium concentration in the solution/suspension can vary from as low as 0.01% by weight to as high as 10% by weight, or greater. In some embodiments, titanium concentration ranging from about 0.5 to 5% by weight has given good results.

The TiOₓ precursor solution/suspension can be spread using various conventional methods. In some embodiments, spin casting is used and has provided good results.

The TiOₓ, layer is formed by heating the solution of starting materials for a time period and at a temperature suitable to react the starting materials but not so high as to cause conversion of the starting materials to a full stoichiometric oxide. Temperatures of from about 50 degrees centigrade to about 150 degrees centigrade and times of from about 0.1 hour (at higher temperatures) to about 12 hours (at lower temperatures) can be employed. In some embodiments, the temperature can range from about 80 degrees centigrade to about 120 degrees centigrade for a time period from a few minutes to 1 to 4 hours, with the higher temperatures using the shorter times and the lower temperatures needing the longer times.

It is desirable to exclude oxygen during the casting and heating of the solution of TiOₓ precursors. This prevents premature conversion of the precursor to TiOₓ or conversion of the TiOₓ precursor to TiO₂ full oxide. This can be accomplished by carrying out the casting and solution preparation under vacuum or in an inert atmosphere such as argon or nitrogen atmosphere.

In some embodiments, an additional TiOₓ may be formed on top of the second charge separation layer in the back cell and adjacent to the cathode electrode. This additional TiOₓ layer can be similar formed by using a sol-gel processed TiOₓ precursor solution.

While the invention is not limited to any theories, it is believed that the TiOₓ layer may serve the following functions and provide advantages.

First, when a TiOₓ, layer is deposited between the second charge separation layer of the back cell and the cathode, the TiOₓ, layer may functions as an optical spacer that redistributes the light intensity to optimize the efficiency of the back cell.

Second, by introducing a TiOₓ layer between the charge separating layer of the back cell and the cathode, excellent air stability can be achieved. The TiOₓ layer may act as a shielding and scavenging layer which prevents intrusion of oxygen and humidity into the electronically active polymers, thereby improving the lifetime of unpackaged devices exposed to air by nearly two orders of magnitude.

Third, the TiOₓ may function as an electron transport layer. As a result of the oxygen deficiency, the TiOₓ layer is n-type doped. As a result, the inclusion of a TiOₓ layer between the charge separating layer of the back cell and the aluminum cathode does not result in an increase in the series resistance. Moreover, since the lowest energy states at the bottom of the conduction band of TiOₓ are well matched to the Fermi energy of aluminum, there is facile electron transfer from the TiOₓ electron transport layer to the aluminum cathode.

Fourth, the TiOₓ layer breaks the symmetry in the front cell, thereby creating an open circuit voltage.

Fifth, the TiOₓ function may as a hole blocking layer since the top of the valence band of TiOₓ is sufficiently electronegative, 8.1 eV below the vacuum, to block holes.

Sixth, a TiOₓ layer enables or facilitates fabrication of tandem photovoltaic devices. The transparent TiOₓ layer can be used to separate and connect the front cell and the back cell. The TiOₓ layer may serve as an electron transport and collecting layer for the front cell and as a stable foundation that enables the fabrication of the second cell to complete the tandem cell architecture. Because TiOₓ is hydrophilic, it may function as a separator, allowing a hole transporting layer such as PEDOT:PSS layer to be cast from an aqueous solution on top of a hydrophobic charge separation layer in the front cell such as PCPDTBT:PCBM layer. The hydrophobic TiOₓ, precursor becomes hydrophilic after conversion to TiOₓ.

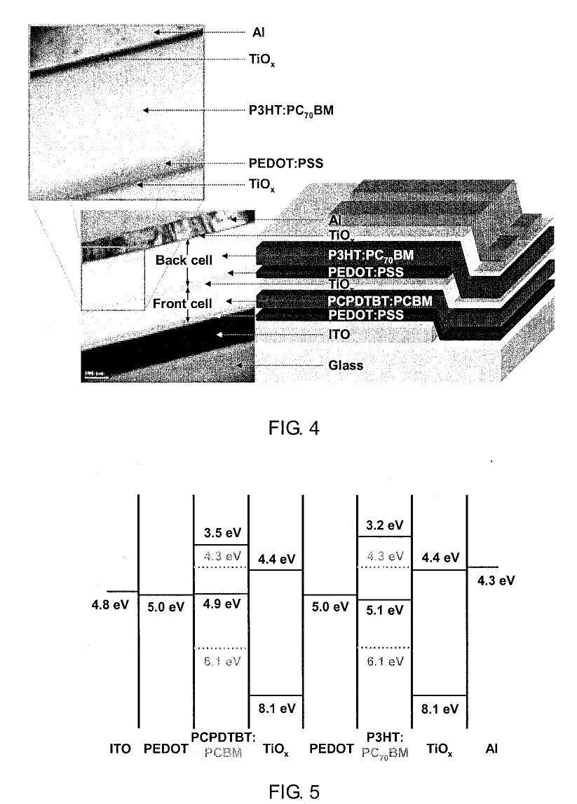

FIG. 4 illustrates an exemplary embodiment of a polymer photovoltaic device in tandem architecture. The charge separation layer in the front cell is a bulk heterojunction composite of poly[2,6-(4,4-bis-(2-ethylhexyl)-4H-cyclopenta[2,1-b;3,4-b′]dithiophene)-alt-4,7-(2,1,3-benzothiadiazole)] (“PCPDTBT” or “ZZ50”) and [6,6]-phenyl-C61 butyric acid methyl ester (“PCBM”). The charge separation layer in the back cell is a bulk heterojunction composite of poly(3-hexylthiophene) (“P3HT”) and [6,6]-phenyl-C71 butyric acid methyl ester (“PC₇₀BM”). The two polymer-fullerene composite layers are separated by a substantially transparent TiOₓ layer and a highly conductive hole transporting layer PEDOT:PSS (Baytron PH500). Electrons from the front cell combine with holes from the back cell at the TiOₓ-PEDOT:PSS interface.

Cross-sectional images of the polymer tandem photovoltaic device taken with high resolution transmission electron microscopy (TEM) are shown on the left in FIG. 4. The TEM images clearly show the individual layers with sharp interfaces. There is no inter-layer mixing.

FIG. 5 is an energy level diagram illustrating the highest occupied molecular orbital (HOMO) energies and the lowest unoccupied molecular orbital (LUMO) energies of the individual component materials used in the photovoltaic device illustrated in FIG. 4.

In some embodiments, the tandem photovoltaic devices use a wide band gap material as the charge separation layer for the front cell and a narrow band gap material as the charge separation layer for the back cell. The front cell can be thinner than the back cell so that the photocurrents generated in each sub-cell are balanced. In the photovoltaic device having the structure as illustrated in FIG. 4, due to the phase morphology of the PCPDTBT:PCBM composite, increasing the film thickness of this layer above 130 nm may lead to reduced values for both J_{SC} and FF in the single cells. However, the J_{SC} of the P3HT:PC₇₀BM single cell increases as the film thickness increases up to 200 nm beyond which the FF is reduced. Because of these material characteristics, an “inverted structure,” i.e., with the narrow band gap bulk heterojunction composite (PCPDTBT:PCBM) in the front cell and the wide band gap bulk heterojunction composite (P3HT:PC₇₀BM) in the back cell may be used.

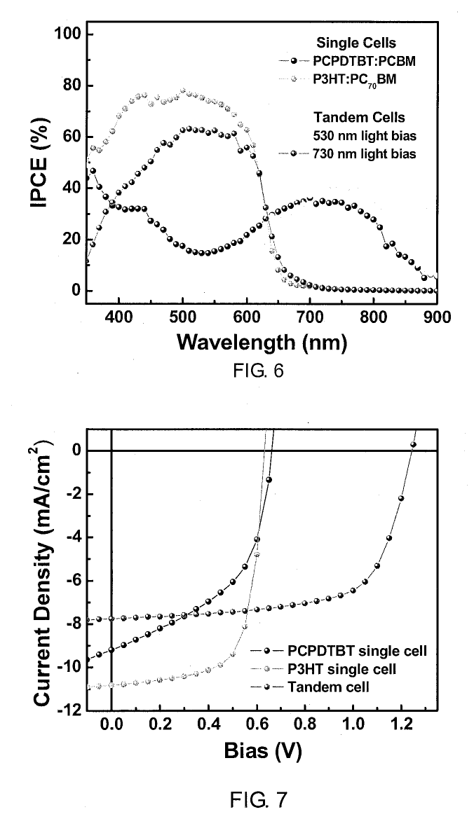

FIG. 6 illustrates incident photon-to-current collection efficiency (IPCE) spectra of both the single cells and of the tandem device using a bias light on the tandem device. The IPCE spectra confirms the series connection of the sub-cells and the full spectral coverage of the tandem device. The spectrum of P3HT:PC₇₀BM composite gives a maximum IPCE of about 78% at 500 nm. The spectrum of PCPDTBT:PCBM composite has two dominant peaks, one being approximately 35% at 750-800 nm and the other over 32% at below 440 nm. These spectral responses are in excellent agreement with the absorption spectra of the two composites illustrated in FIG. 3. When carrying out the measurements on the tandem device, it is noted that biasing the device with 530 nm blue light selectively excites the front cell, and biasing with 730 nm red light selectively excites the back cell, indicating that the device harvests photons from the UV to near IR, and that each sub-cell functions individually.

FIG. 7 illustrates the current density v. voltage (J-V) characteristics of single cells and the tandem device using PCPDTBT:PCBM and P3HT:PC₇₀BM composites under AM1.5G illumination from a calibrated solar simulator with irradiation intensity of 100 mW/cm². The photovoltaic response with device performance for each sub-cell are as follows: the PCPDTBT:PCBM single cell yields J_{SC}=9.2 mA/cm², V_{OC}=0.66 V, FF=0.50, and ηₑ=3.0%, and the P3HT:PC₇₀BM single cell yields J_{SC}=10.8 mA/cm², V_{OC}=0.63 V, FF=0.69, and ηₑ=4.7%.

With two sub-cells stacked in series, the current that is extracted from the tandem device is determined by the current generated in either the front or the back cell, whichever is smaller. Accordingly, when there is greater carrier generation in either sub-cell, these excess charges cannot contribute to the photocurrent and so compensate for the built-in potential across that sub-cell. This compensation leads to a reduced V_{OC} in the tandem device. To optimize and balance the current in each sub-cell, variations of the order of the photoactive materials, the concentration and ratio of each component in the composite solutions, and the thicknesses of the two bulk heterojunction materials can be made. In the exemplary embodiment shown in FIG. 4, because of the high extinction coefficient of the PCPDTBT:PCBM composite, the P3HT:PC₇₀BM back cell has a smaller J_{SC} of the two sub-cells, and is thus the limiting cell. The FF of the tandem device is very close to the FF of the limiting cell. P3HT:PC₇₀BM is used in the back cell to obtain a higher FF. Using the inverted structure illustrated in FIG. 4, more than 20 tandem devices were fabricated with efficiencies above 6.2%. Typical performance parameters were as follows: J_{SC}=7.8 mA/cm², V_{OC}=1.24 V, FF=0.67 and ηₑ=6.5%. The J_{SC} in the tandem device was consistent with the IPCE measurements since the photo-current in the back cell from IPCE is 72% of that of P3HT:PC₇₀BM single cell, confirming that the back cell is the limiting cell for J_{SC} as well as FF.

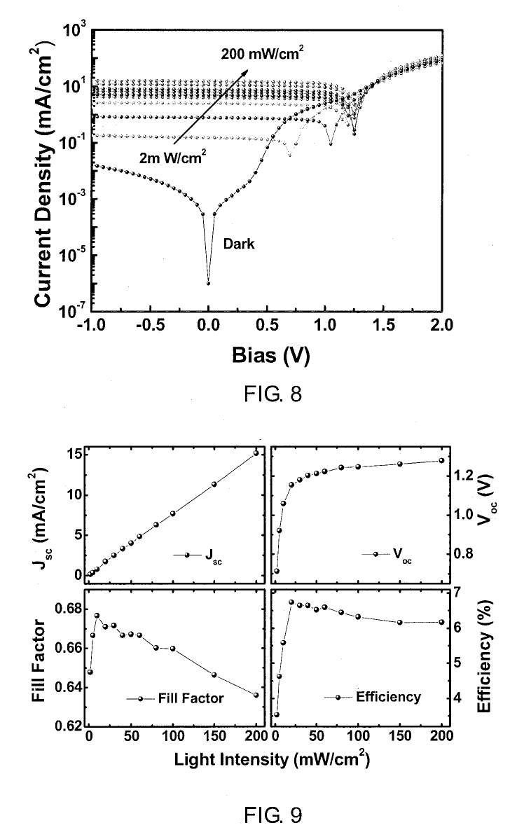

FIG. 8 illustrates the J-V characteristics of the inverted tandem photovoltaic device shown in FIG. 4, measured with different incident light intensity from 0 to 200 mW/cm². In FIG. 9, the performance parameters of the tandem device (J_{SC}, V_{OC}, FF, and ηₑ) are plotted as functions of the incident light intensity. Since J_{SC} is linear with illuminated light intensity, there is no significant space charge buildup in the tandem device. The V_{OC} also increases monotonically with an increase in the light intensity and approaches 1.3V under AM1.5 conditions at 200 mW/cm², the sum of V_{OC} of the two sub-cells. The FF approaches 0.68 at 10 mW/cm², a value close to the FF of the limiting P3HT:PC₇₀BM back cell, and exceeds 0.63 at 200 mW/cm². The power conversion efficiency of the tandem device reaches its maximum of ηₑ=6.7% at 20 mW/cm², while ηₑ=3.5% at 2 mW/cm² and ηₑ=6.1% at 200 mW/cm². With these performance parameters, it is evident that the sub-cells in the tandem cell are connected in series, and provide enhanced coverage of the solar spectrum.

This invention will be further described with reference to the following Examples. The Examples are provided to illustrate the invention and are not intended to limit the scope of the invention in any way.

### Example 1

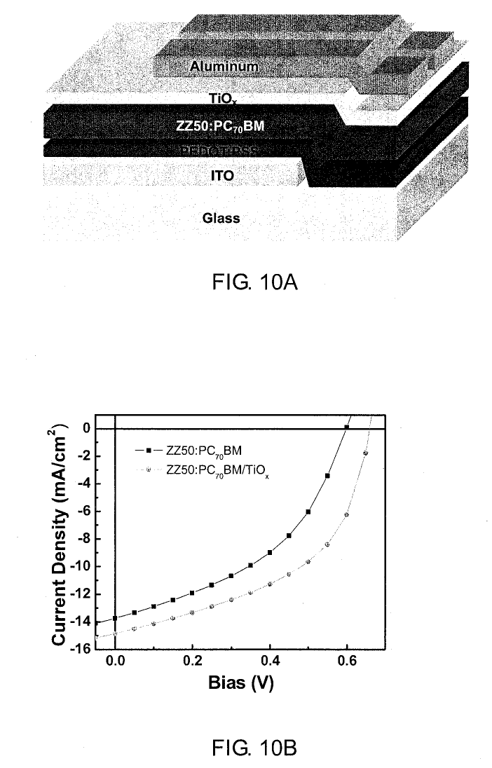

This example illustrates preparation of a single cell device having the structure as illustrated in FIG. 10A using ZZ50:PC₇₀BM composite film as the bulk heterojunction layer. The details of the device fabrication are as follows:

Solvent: Chlorobenzene was used as the solvent for ZZ50:PC₇₀BM solution.

ZZ50:PC₇₀BM ratio and concentration: The best device performance was achieved when the mixed solution had ZZ50/PC₇₀BM ratio of 1.0:3.6, i.e. with a concentration of 0.7 wt % ZZ50 and 2.5 wt % PC₇₀BM in chlorobenzene.

Device fabrication procedure: An ITO-coated glass substrate was first cleaned with detergent, then ultrasonicated in acetone and isopropyl, and subsequently dried in an oven overnight. Conducting poly(3,4-ethylenedioxylenethiophene)-polystylene sulfonic acid (PEDOT:PSS, Baytron P) was spin-cast at 5000 rpm with a thickness of about 70 nm from an aqueous solution (after passing a 0.45 μm filter). The substrate was dried for 10 minutes at 140° C. in air, and then moved into a glove box for spin-casting the photoactive layer. A chlorobenzene solution comprised of ZZ50 (0.7 wt %) and PC₍₇₀₎BM (2.5 wt %) was then spin-cast at 3000 rpm with a thickness of about 80 nm on top of the PEDOT layer. Then a TiOₓ precursor solution in methanol was spin-cast at 5000 rpm with a thickness of about 30 nm in air on top of the polymer-fullerene derivatives composite layer. Subsequently, during 10 minutes in air at 80° C., the precursor converted to TiOₓ layer by hydrolysis. Subsequently the device was pumped down in vacuum about 10⁻⁷ torr, and an Al electrode of about 150 nm thick was deposited on top of the TiOₓ layer. The deposited Al electrode area defined the active area of the devices as 4.5 mm².

Calibration and measurement: For calibration of the solar simulator, the mismatch of the spectrum (the simulating spectrum) obtained from the Xenon lamp (300 W Oriel) and the solar spectrum using an AM1.5G filter was carefully minimized. Then the light intensity was calibrated using calibrated standard silicon photovoltaic (PV) solar cells obtained from the National Renewable Energy Laboratory (NREL). Measurements were conducted inside a glove box using a high quality optical fiber to guide light from a solar simulator outside the glove box. The illumination intensity and spectrum of the solar simulator were calibrated directly with an Oriel 1 kW solar simulator (Model 91193; AM1.5G). Current density-voltage curves were measured with a Keithley 236 source measurement unit.

FIG. 10B shows the current density v. voltage (J-V) characteristics of the single solar cells using ZZ50:PC₇₀BM composite under AM1.5G illumination from the calibrated solar simulator with irradiation intensity of 100 mW/cm². To determine the role of TiOₓ, devices with and without a TiOₓ, layer were fabricated using the same procedures and under the same conditions, except for the TiOₓ deposition.

The device without a TiOₓ layer had the following performance: J_{SC}=13.75 mA/cm², V_{OC}=0.60 V, FF=0.44, and ηₑ=3.60%. The device with a TiOₓ, layer showed substantially improved device performance: J_{SC}=14.86 mA/cm², V_{OC}=0.66 V, FF=0.49, and ηₑ=4.83%.

### Example 2

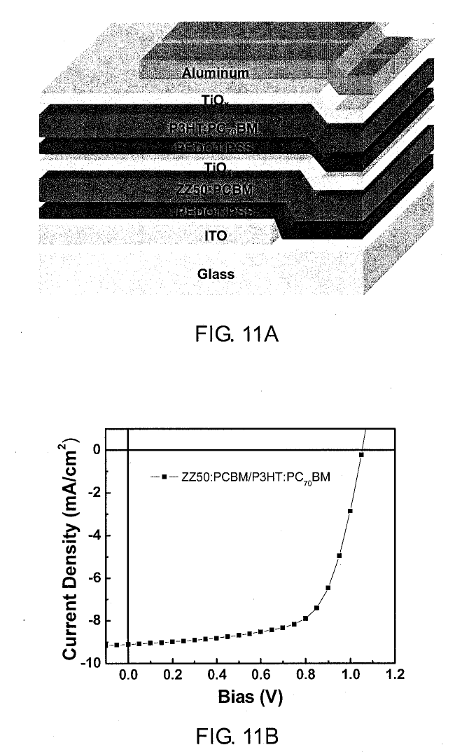

This Example illustrates preparation of polymer tandem photovoltaic devices having an “inverted structure,” i.e., with a low band gap polymer in the first charge separation layer of the front sub-cell and a high band gap polymer in the second charge separation layer of the back sub-cell. As shown in FIG. 11A, P3HT:PC₇₀BM and ZZ50:PCBM composite films were used as bulk heterojunction layers. The details of the device fabrication are as follows:

Solvent: Chlorobenzene was used as the solvent for ZZ50:PCBM solutions, and chloroform was used as the solvent for P3HT:PC₇₀BM solution.

P3HT/PC₇₀BM and ZZ50:PCBM ratio and concentration: The best device performance was achieved when the mixed solution had ZZ50/PCBM ratio of 1.0:3.6, i.e. with a concentration of 0.7 wt % ZZ50 and 2.5 wt % PCBM in chlorobenzene, and P3HT/PC₇₀BM ratio of 1.0:0.7, i.e. with a concentration of 1 wt % P3HT and 0.7 wt % PCBM in chloroform.

Device fabrication procedure: An ITO-coated glass substrate was first cleaned with detergent, then ultrasonicated in acetone and isopropyl, and subsequently dried in an oven overnight. Conducting poly(3,4-ethylenedioxylenethiophene)-polystylene sulfonic acid (PEDOT:PSS, Baytron P) was spin-cast at 5000 rpm with a thickness of about 70 nm from an aqueous solution (after passing a 0.45 μm filter). The substrate was dried for 10 minutes at 140° C. in air, and then moved into a glove box for spin-casting the photoactive layer. A chlorobenzene solution comprised of ZZ50 (0.7 wt %) and PCBM (2.5 wt %) was then spin-cast at 2000 rpm with a thickness of about 130 nm on top of the PEDOT layer for the first charge separation layer of the front cell. Then, a TiOₓ precursor solution in methanol was spin-cast at 5000 rpm with a thickness of about 30 nm in air on top of the polymer-fullerene derivatives composite layer. Subsequently, during 10 minutes in air at 80° C., the precursor converted to TiOₓ, by hydrolysis.

The second charge separation layer of the photovoltaic device: High conducting PEDOT:PSS (Baytron PH500) was spin-cast at 5000 rpm with a thickness of about 70 nm. The stack was then moved into a glove box for drying and spin-casting the second charge separation layer of P3HT/PC₇₀BM. The substrate was dried for 10 minutes at 120° C. in the glove box after spin-coating of the PEDOT layer outside. A chloroform solution comprised of P3HT (1 wt %) and PC₇₀BM (0.7 wt %) was then spin-cast at 1500 rpm with a thickness of about 170 nm on top of the PEDOT layer to form the second charge separation layer. Then, a TiOₓ precursor solution in methanol was spin-cast with a thickness of about 30 nm in air on top of the polymer-fullerene composite to form an electron transport layer. Subsequently, during 10 minutes in air at 80° C., the precursor converted to TiOₓ by hydrolysis.

The device was subsequently pumped down in vacuum (˜10⁻⁷ torr), and Al electrode with a thickness of about 150 nm was deposited. The deposited Al electrode area defined an active area of the devices as 4.5 mm². After fabrication the devices were annealed at 155° C. for 5 minutes. The tandem photovoltaic device thus obtained had the following structure: ITO/170 nm PEDOT/130 nm ZZ50:PCBM/30 nm TiOₓ/70 nm PEDOT/170 nm P3HT:PC₇₀BM/30 nm TiOₓ/150 nm Al.

Calibration and measurement: The same procedures as described in Example 1 were used.

FIG. 11B shows the current density v. voltage (J-V) characteristics of the tandem photovoltaic device using ZZ50:PCBM and P3HT:PC₇₀BM composites under AM1.5G illumination from a calibrated solar simulator with irradiation intensity of 100 mW/cm². The device had the following performance features: J_{SC}=9.11 mA/cm², V_{OC}=1.05 V, FF=0.66 and ηₑ=6.32%.

### Example 3

Using the similar method described in EXAMPLE 2, three more polymer tandem photovoltaic devices having the structure as illustrated in FIG. 11A were fabricated using P3HT:PC₇₀BM and ZZ50:PCBM composite films as active charge separation layers. Different spin speed was used for each layer in this Example to optimize device performance.

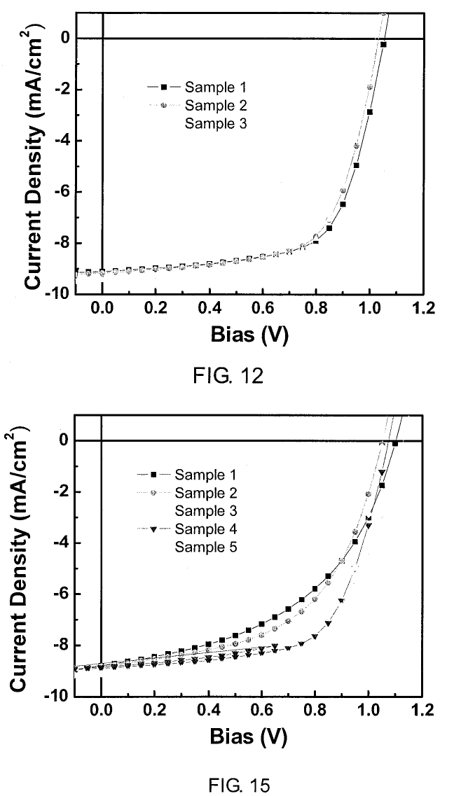

FIG. 12 shows the corresponding data obtained under AM1.5G illumination from a calibrated solar simulator with irradiation intensity of 100 mW/cm². In Sample 1, ZZ50:PCBM composite was spin-cast at 2000 rpm with a thickness of about 130 nm on top of the PEDOT layer. In Samples 2 and 3 the active layers were spin-cast at 2500 rpm with a thickness of about 100 nm and at 3000 rpm with a thickness of about 80 nm, respectively. The devices with different thicknesses of ZZ50:PCBM layer provided the following device performance: Sample 1 (˜130 nm ZZ50:PCBM): J_{SC}=9.11 mA/cm², V_{OC}=1.05 V, FF=0.66 and ηₑ=6.32%; Sample 2 (˜100 nm ZZ50:PCBM): J_{SC}=9.17 mA/cm², V_{OC}=1.03 V, FF=0.66 and ηₑ=6.19%; and Sample 3 (˜80 nm ZZ50:PCBM): J_{SC}=9.44 mA/cm², V_{OC}=1.02 V, FF=0.65 and ηₑ=6.26%.

In this Example 3, changing the thickness of the first charge separation layer caused minor changes in V_{OC} and J_{SC}. However the efficiencies of all three photovoltaic devices were approximately 6.3%. The thinner first charge separation layer showed lower V_{OC} and higher J_{SC} than the thicker first charge separation layer, while fill factor remained at around 0.66. The different thickness of the first charge separation layer led to a trade-off with V_{OC} and J_{SC} in tandem photovoltaic devices.

### Example 4

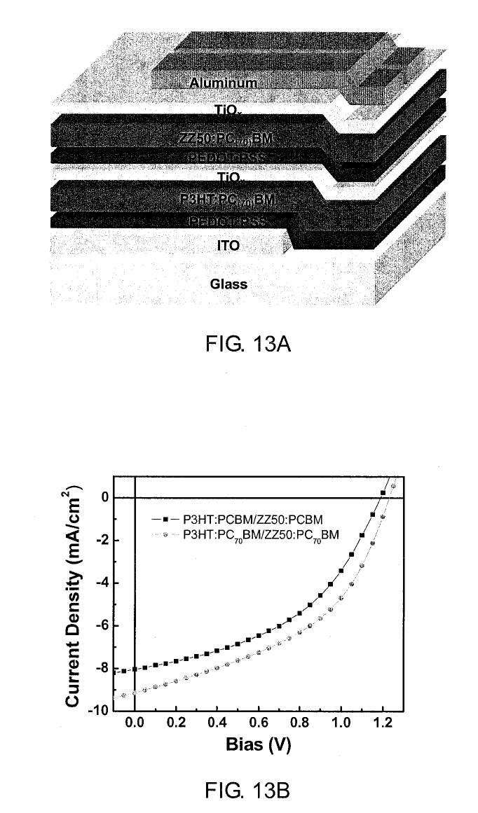

This Example illustrates preparation of polymer tandem photovoltaic devices having a “non-inverted structure,” i.e., with a high band gap polymer in the first charge separation layer of the front sub-cell and a low band gap polymer in the second charge separation layer of the back sub-cell. As shown in FIG. 13A, P3HT:PC₇₀BM and ZZ50:PCBM composite films were used as bulk heterojunction layers. The details of the device fabrication are as follows:

Solvent: Chlorobenzene was used as the solvent for ZZ50:PC₇₀BM solutions, and chloroform was used as the solvent for P3HT:PC₇₀BM solution.

P3HT/PC₇₀BM and ZZ50:PCBM ratio and concentration: The best device performance was achieved when the mixed solution had ZZ50/PC₇₀BM ratio of 1.0:3.6, i.e. with a concentration of 0.7 wt % ZZ50 and 2.5 wt % PCBM in chlorobenzene, and P3HT/PC₇₀BM ratio of 1.0:0.7, i.e. with a concentration of 1 wt % P3HT and 0.7 wt % PCBM in chloroform.

Device fabrication procedure: An ITO-coated glass substrate was first cleaned with detergent, then ultrasonicated in acetone and isopropyl, and subsequently dried in an oven overnight. Conducting poly(3,4-ethylenedioxylenethiophene)-polystylene sulfonic acid (PEDOT:PSS, Baytron P) was spin-cast at 5000 rpm with a thickness of about 70 nm from an aqueous solution (after passing a 0.45 μm filter). The substrate was dried for 10 minutes at 140° C. in air, and then moved into a glove box for spin-casting the photoactive layer. A chloroform solution comprised of P3HT (1 wt %) and PC₇₀BM (0.7 wt %) was then spin-cast at 3000 rpm with a thickness of about 100 nm on top of the PEDOT layer. Then a layer of TiOₓ, precursor solution in methanol was spin-cast at 5000 rpm with a thickness of about 30 nm in air on top of P3HT/PC₇₀BM composite. Subsequently, during 10 minutes in air at 80° C. the precursor converted to TiOₓ, by hydrolysis.

High conducting PEDOT:PSS (Baytron PH500) was spin-cast at 5000 rpm with a thickness of about 70 nm and then moved into a glove box for drying and spin-casting the second charge separation layer. The substrate was dried for 10 minutes at 120° C. in the glove box after spin-coating of the PEDOT layer. A chlorobenzene solution comprised of ZZ50 (0.7 wt %) and PCBM (2.5 wt %) was then spin-cast at 3000 rpm with a thickness of about 80 nm on top of the PEDOT layer. Then, a TiOₓ precursor solution in methanol was spin-cast with a thickness of about 30 nm in air on top of ZZ50/PCBM composite. Subsequently, during 10 minutes in air at 80° C., the precursor converted to TiOₓ by hydrolysis. The tandem photovoltaic device thus obtained had the following structure: ITO/70 nm PEDOT/100 nm P3HT:PC₇₀BM/30 nm TiOₓ/70 nm PEDOT/80 nm ZZ50:PC₇₀BM/30 nm TiOₓ/150 nm Al.

The device was subsequently pumped down in vacuum (˜10⁻⁷ torr). An Al electrode with a thickness of about 150 nm was deposited on top. The deposited Al electrode area defined an active area of the devices as 4.5 mm². After fabrication the devices were annealed at 155° C. for 5 minutes.

Calibration and measurement: The measurement procedures were the same as described in Example 1.

FIG. 13B shows the current density v. voltage (J-V) characteristics of the obtained tandem photovoltaic device under AM1.5G illumination from a calibrated solar simulator with irradiation intensity of 100 mW/cm². Note that the data shown with squares used C₆₀ in the PCBM and the data shown with dots used C₇₀ in the PCBM.

The device had the following performance: For the P3HT:PCBM/ZZ50:PCBM device: J_{SC}=8.05 mA/cm², V_{OC}=1.19 V, FF=0.45 and ηₑ=4.32%. For the P3HT:PC₇₀BM/ZZ50:PC₇₀BM device: J_{SC}=9.15 mA/cm²; V_{OC}=1.23 V, FF=0.45 and ηₑ=5.10%.

Better device performance was obtained with PC₇₀BM in both charge separating layers.

### Example 5

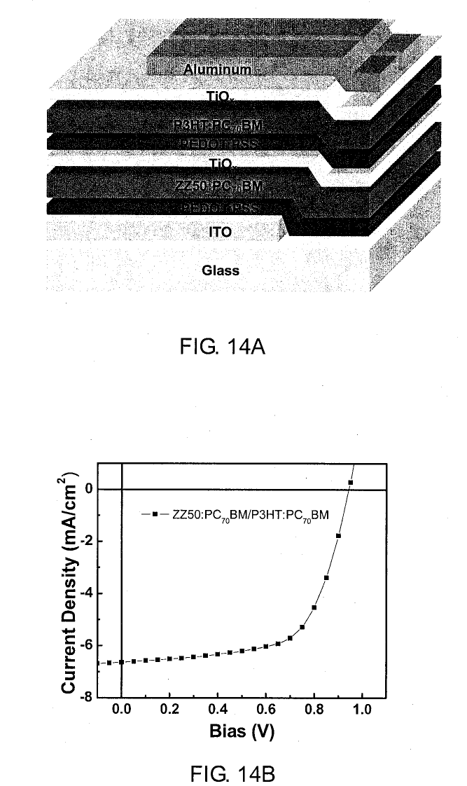

This Example illustrates preparation of polymer tandem photovoltaic devices with an “inverted structure,” i.e., with a low band gap polymer in the charge separation layer of the front sub-cell and a high band gap polymer in the second charge separation layer of the back sub-cell. As shown in FIG. 14A, ZZ50:PC₇₀BM and P3HT:PC₇₀BM composite films were used in the photovoltaic devices. The details of the device fabrication procedures were the same as in Example 2.

Calibration and Measurement procedures were the same as those described in Example 1.

FIG. 14B shows the current density v. voltage (J-V) characteristics of the tandem photovoltaic device using ZZ50:PC₇₀BM and P3HT:PC₇₀BM composites under AM1.5G illumination from a calibrated solar simulator with irradiation intensity of 100 mW/cm². The device performance was as follows: J_{SC}=6.64 mA/cm², V_{OC}=0.94 V, FF=0.64 and ηₑ=4.00%. The first charge separation layer in the front sub-cell with ZZ50:PC₇₀BM composite had more absorption compared to ZZ50:PCBM composite layer in the visible range (see FIG. 2) especially in the range from 400 nm-600 nm. As a result, the light intensity that reaches the second charge separation layer with P3HT:PC₇₀BM layer was thereby reduced causing both J_{SC} and V_{OC} to decrease.

### Example 6

This Example illustrates the effect of variations in TiOₓ layers to tandem photovoltaic devices. Using the similar device fabrication procedures described in Example 2, five more solution-processible polymer tandem photovoltaic devices having the structure as shown in FIG. 5 were fabricated using P3HT:PC₇₀BM and ZZ50:PCBM composite films.

Calibration and measurement procedures were the same as those described in Example 1.

The corresponding data for Samples 1 through 5 obtained under AM1.5 illumination from a calibrated solar simulator with irradiation intensity of 100 mW/cm² are shown in FIG. 15.

Sample 1: Tandem photovoltaic device without TiOₓ had the following device performance: J_{SC}=8.79 mA/cm², V_{OC}=1.10 V, FF=0.48, and ηₑ=4.66%.

Samples 2, 3, 4, and 5: Tandem photovoltaic devices with TiOₓ layers demonstrated substantially improved device performance. Since the device efficiency is proportional to the product J_{SC} V_{OC} FF, most of the increase in the device efficiency resulted from the increased FF (about 40% increase in a device with TiOₓ, layer) rather than from changes in V_{OC} or J_{SC}. For Samples 2 to 5, the TiOₓ, layers were spin-cast at 5000 rpm with a thickness of about 30 nm using different solvent ratios (methanol (MeOH):isopropanol (IPA)) in TiOₓ sol. The devices with different solvent ratio had the following device performances:

Sample 2 (MeOH:IPA=5:5): J_{SC}=8.81 mA/cm² V_{OC}=1.05 V, FF=0.54 and ηₑ=5.01%.

Sample 3 (MeOH:IPA=7:3): J_{SC}=8.85 mA/cm², V_{OC}=1.13V, FF=0.59 and ηₑ=5.95%.

Sample 4 (MeOH:IPA=8:2): J_{SC}=8.90 mA/cm², V_{OC}=1.07 V, FF=0.64 and ηₑ=6.11%.

Sample 5 (MeOH only): J_{SC}=9.11 mA/cm², V_{OC}=1.05V, FF=0.66 and ηₑ=6.32%.

### Example 7

This Example illustrates preparation of a tandem photovoltaic device with an “inverted structure” shown in FIG. 4. A low band gap polymer was used in the first charge separation layer of the front sub-cell and a high band gap polymer was used in the second charge separation layer of the back sub-cell.

TiOₓ synthesis: The TiOₓ material was prepared using a novel sol-gel procedure as follows: Titanium(IV) isopropoxide (Ti[OCH(CH₃)₂]4, Aldrich, 99.999%, 10 mL) was prepared as a precursor, and mixed with 2-methoxyethanol (CH₃OCH₂CH₂OH, Aldrich, 99.9+%, 50 mL) and ethanolamine (H₂NCH₂CH₂OH, Aldrich, 99+%, 5 mL) in a three-necked flask each connected with a condenser, thermometer, and argon gas inlet/outlet. Then, the mixed solution was heated to 80° C. for 2 hours in silicon oil bath under magnetic stirring, followed by heating to 120° C. for 1 hour. The two-step heating (at 80° C. and 120° C.) was then repeated. The TiOₓ precursor solution was prepared in isopropyl alcohol.

Dense TiOₓ layers were prepared from the TiOₓ precursor solution. The precursor solution was spin-cast in air on top of the semiconducting polymer layer with thicknesses in the range of 20-30 nm. Subsequently, the films were heated at 80° C. for 10 minutes in air. During this process the precursor converted to a solid-sate TiOₓ layer by hydrolysis. The resulting TiOₓ films were transparent and smooth with surface features smaller than a few nm. Analysis by X-ray Photoelectron Spectroscopy (XPS) revealed an oxygen deficiency at the surface of the thin film samples with Ti:O ratio as 42.1:56.4 (% ratio), hence the composition was designated as TiOₓ.

Tandem photovoltaic devices, with each of the layers processed from solution, were fabricated using PCPDTBT:PCBM and P3HT:PC₇₀BM composite films. The details of the device fabrication were as follows.

Solvent: Chlorobenzene was used as the solvent for PCPDTBT:PCBM solutions, and chloroform was used as the solvent for P3HT:PC₇₀BM solution.

PCPDTBT:PCBM and P3HT/PC₇₀BM ratio and concentration: The best device performance was achieved when the mixed solution had PCPDTBT:PCBM ratio of 1.0:3.6, i.e. with a concentration of 0.7 wt % PCPDTBT and 2.5 wt % PCBM in chlorobenzene, and P3HT:PC₇₀BM ratio of 1.0:0.7, i.e. with a concentration of 1 wt % P3HT and 0.7 wt % PC₇₀BM in chloroform.

Device fabrication procedure: An ITO-coated glass substrate was first cleaned with detergent, then ultrasonicated in acetone and isopropyl, and subsequently dried in an oven overnight. Conducting poly(3,4-ethylenedioxylenethiophene)-polystylene sulfonic acid (PEDOT:PSS, Baytron P) was spin-cast at 5000 rpm with a thickness of about 40 nm from an aqueous solution (after passing a 0.45 μm filter). The substrate was dried for 10 minutes at 140° C. in air, and then moved into a glove box for spin-casting of the photoactive layer. The chlorobenzene solution comprised of PCPDTBT (0.7 wt %) and PCBM (2.5 wt %) was then spin-cast at 2000 rpm with a thickness of about 130 nm on top of the PEDOT layer to form the first charge separation layer of the front sub-cell. Then, for the separation layer, the TiOₓ, precursor solution in methanol was spin-cast at 5000 rpm with a thickness of about 20 nm in air on top of the polymer-fullerene derivatives composite layer. After 10 minutes in air at 80° C., the precursor was converted to TiOₓ) by hydrolysis.

For the second charge separation layer in the back sub-cell, highly conductive PEDOT:PSS (Baytron PH500) was spin-cast at 5000 rpm with a thickness of about 40 nm. Subsequently, the portion of this layer that was on the section of the glass slide not covered with ITO was washed off in order to prevent paralleled interconnection with other active pixels and also to avoid the large area effect. The cell was then moved into a glove box and dried for 10 minutes at 120° C. The chloroform solution comprised of P3HT (1 wt %) and PC₇₀BM (0.7 wt %) was then spin-cast at 1500 rpm with a thickness of about 170 nm on top of the PEDOT layer for the second charge separation layer of the back sub-cell. Then, for the electron transport layer of the second charge separation layer, a TiOₓ precursor solution in methanol was spin-cast with a thickness of about 20 nm in air on top of the polymer-fullerene composite layer. During 10 minutes in air at 80° C., the precursor converted to TiOₓ by hydrolysis.

Finally, the device was pumped down in vacuum (˜10⁻⁷ torr), and an Al electrode with a thickness of about 100 nm was deposited on top. The deposited Al electrode area defined an active area of the devices as 4.5 mm². After fabrication the devices were annealed at 160° C. for 5 minutes. The structure of the tandem photovoltaic devices thus obtained had the following structure: ITO/40 nm PEDOT/130 nm ZZ50:PCBM/20 nm TiOₓ/40 nm PEDOT/170 nm P3HT:PC₇₀BM/20 nm TiOₓ/100 nm Al. The structures of the PCPDTBT:PCBM single cell and P3HT:PC₇₀BM single cell were as follows: ITO/40 nm PEDOT/130 nm PCPDTBT:PCBM/20 nm TiOₓ/Al and ITO/40 nm PEDOT/170 nm P3HT:PC₇₀BM/20 nm TiOₓ/Al, respectively.

Calibration and measurement: For calibration of the solar simulator, any mismatch of the spectrum (the simulating spectrum) obtained from the Xenon lamp (300 W Oriel) and the solar spectrum was carefully minimized using an AM1.5G filter. Then the light intensity was calibrated using calibrated standard silicon solar cells with a proactive window made from KG5 filter glass obtained from the National Renewable Energy Laboratory (NREL). Measurements were conducted with the devices inside a glove box using a high quality optical fiber to guide light from a solar simulator outside the glove box. Current density-voltage curves were measured with a Keithley 236 source measurement unit.

Cross-section TEM images: To prepare the solar cell cross sections, about 200 nm-thick SiO₂ layer was deposited on top of the device using electron beam evaporator (BOC Edwards Temescal) to prevent sample damage. Next, a focused ion beam (FEI Strata) was used to cut a thin slide (about 130 nm thick) of the sample (4 μm×15 μm), which was then transferred onto a TEM grid for imaging using a micromanipulator with a glass needle. The TEM images were collected in bright-field mode (FEI Tecnai G2 Sphera Microscope).

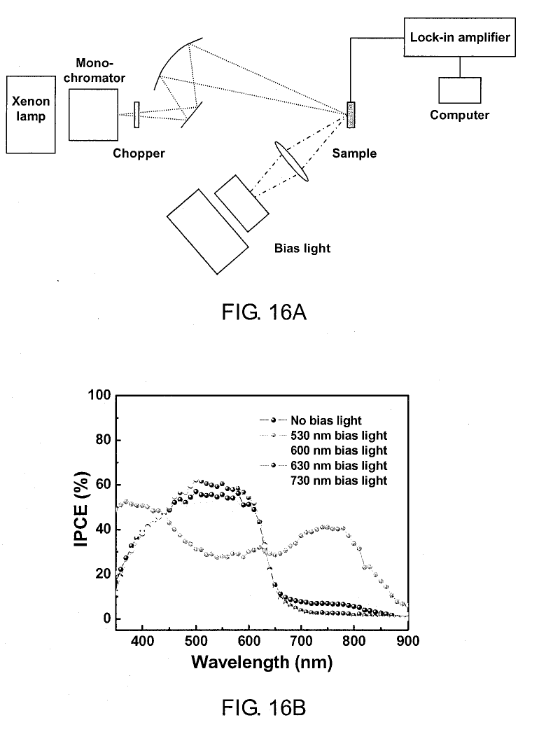

Absorption and IPCE measurement: The absorption spectra were recorded using a spectrometer (Shimadzu UV-2401 PC). The IPCE measurements for the single cells and unbiased tandem device were conducted with a mechanically chopped 250W xenon lamp directed into a McPherson monochromator as the light source, and with the photocurrent from the devices being determined with a typical lock-in amplifier technique. FIG. 16A illustrates the experimental setup for IPCE of a tandem device with bias light. For tandem device measurements made with bias light, an unmodulated 300W xenon lamp and Newport 77250 monochromator were added to the experimental setup to serve as the secondary light source, and the light from the second monochromator was focused onto the region of the cell being illuminated with the first light source. FIG. 16B illustrates IPCE spectra of a tandem cell without bias light and with bias light from 530 nm to 730 nm. The IPCE measurements were conducted using modulation spectroscopy and a lock-in amplifier. The monochromatic bias light source was unmodulated with intensity of approximately 2 mW/cm².

A polymer tandem photovoltaic device has been described in which each of the individual layers is processed from solution without significant interlayer mixing. This represents a major step toward the achievement of high efficiency solar cells that can be fabricated in large areas using low cost printing and coating technologies. The use of TiOₓ as a separator, electron transport layer, hole blocking layer, symmetry breaking layer, and optical spacer in fully solution processible polymer tandem solar cells is an important development step toward large scale commercialization.

The following documents include information generally related to this invention and are incorporated herein by reference in their entirety.
1. N. S. Sariciftci, L. Smilowitz, A. J. Heeger, F. Wudl, Science 258, 1474 (1992).
2. N. S. Sariciftci and A. J. Heeger, U.S. Pat. No. 5,454,880
3. G. Yu, J. Gao, J. C. Hemmelen, F. Wudl, A. J. Heeger, Science 270, 1789 (1995).
4. C. J. Brabec, N. S. Sariciftci, J. C. Hummelen, Adv. Funct. Mater. 11, 15 (2001).
5. C. J. Brabec, Sol. Energy Mater. Sol. Cells 83, 273 (2004).
6. S. E. Shaheen, C. J. Brabec, N. S. Sariciftci, F. Padinger, T. Fromherz, J. C. Hummelen, Appl. Phys. Lett. 78, 841 (2001).
7. F. Padinger, R. Rittberger, and N. S. Sariciftci, Adv. Funct. Mater. 13, 85 (2003).
8. L. A. A. Pettersson, L. S. Roman, O. Inganäs, J. Appl. Phys. 86, 487 (1999).
9. T. Stübinger and W. Brütting, J. Appl. Phys. 90, 3632 (2001).
10. H. Hänsel, H. Zettl, G. Krausch, R. Kisselev, M. Thelakkat, and H-W. Schmidt, Adv. Mater 15, 2056 (2003).
11. H. J. Snaith, N. C. Greenham, and R. H. Friend, Adv. Mater 16, 1640 (2004).
12. C. Melzer, E. J. Koop, V. D. Mihaletchi, and P. W. M. Blom, Adv. Func. Mater. 14, 865 (2004).
13. B. O'Regan, M. Gräzel, Nature 353, 737 (1991).
14. U. Bach, D. Lupo, P. Comte, J. E. Moser, F. Weissörtel, J. Salbeck, H. Spreitzel, M. Gräzel, Nature 395, 583 (1998).
15. C. Arango, L. R. Johnson, V. N. Bliznyuk, Z. Schlesinger, Sue A. Carter, H-H., Horhold, Adv. Mater. 12, 1689 (2000).
16. J. Breeze, Z. Schlesinger, S. A. Carter, P. J. Brock, Phys. Rev. B 64, 125205 (2001).
17. P. A. van Hal, M. M. Wienk, J. M. Kroon, W. J. H. Verhees, L. H. Slooff, W. J. H. Van Gennip, R Jonkheijm, R. A. Janssen, Adv. Mater. 15, 118 (2003).
18. M. Thelakkat, C. Schmitz, and H.-W. Schmidt, Adv. Mater. 14, 577 (2002).
19. H. H. Lee, S. H. Kim, J. Y. Kim, K. Lee (unpublished).
20. Y. I. Kim, S. W. Keller, J. S. Krueger, E. H. Yonemoto, G. B. Saupe, T. E. Malouk, J. Phys. Chem. B 101, 2491 (1997).
21. K. Lee, Y. Chang, J. Y. Kim, Thin Solid Films 423, 131 (2003).

What is claimed is:

1. A tandem photovoltaic device comprising:
a first cell configured to receive incident electromagnetic radiation, said first cell comprising a first charge separating layer comprising a first semiconducting polymer adapted to create electric charge carriers generated by electromagnetic radiation;
a second cell configured to receive electromagnetic radiation passing out of said first cell in a light propagation path, said second cell comprising a second charge separating layer comprising a second semiconducting polymer adapted to create electric charge carriers generated by electromagnetic radiation; and
a first titanium oxide layer interposed between said first and second cells, wherein said first titanium oxide layer being substantially amorphous and having a general formula of TiOx here X being a number of 1 to 1.96.

2. The tandem photovoltaic device of claim 1 further comprising a first electrode adjacent to the first cell, a second electrode adjacent to the second cell, and a second titanium oxide layer between the second cell and the second electrode, wherein said second titanium oxide is substantially amorphous and has a general formula of TiOx where X represents a number of 1 to 1.96.

3. The tandem photovoltaic device of claim 1 wherein said first semiconducting polymer has a first band gap, and said second semiconducting polymer has a second band gap, and said first band gap is different from said second band gap.

4. The tandem photovoltaic device of claim 1 wherein said first semiconducting polymer has a first band gap, and said second semiconducting polymer has a second band gap, and said first band gap is lower than said second band gap.

5. The tandem photovoltaic device of claim 1 wherein said first charge separating layer and/or said second charge separating layer comprises a heterojunction layer comprising a semiconducting conjugated polymer and a fullerene derivative.

6. The tandem photovoltaic device of claim 1 wherein said first charge separating layer and/or said second charge separating layer comprises a polymer selected from the group consisting of poly-(3-hexylthiophene) (“P3HT”) and poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”), and a fullerene derivative.

7. The tandem photovoltaic device of claim 1 wherein said first charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and a fullerene derivative, and said second charge separating layer comprises poly-(3-hexylthiophene) (“P3HT”) and a fullerene derivative.

8. The tandem photovoltaic device of claim 1 wherein said first charge separating layer comprises poly-(3-hexylthiophene) (“P3HT”) and a fullerene derivative, and said second charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and a fullerene derivative.

9. The tandem photovoltaic device of claim 1 wherein said first charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and ([6,6]-phenyl-C₆₁-buteric acid methyl ester) (“PCBM”), and said second charge separating layer comprises poly-(3-hexylthiophene) (“P3HT”) and [6,6]-phenyl-C₇₁butyric acid methyl ester (“PC₇₀BM”).

10. The tandem photovoltaic device of claim 1 wherein said first charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and [6,6]-phenyl-C₇₁butyric acid methyl ester (“PC₇₀BM”), and said second charge separating layer comprises poly-(3-hexylthiophene) (“P3HT”) and [6,6]-phenyl-C₇₁butyric acid methyl ester (“PC₇₀BM”).

11. The tandem photovoltaic device of claim 1 wherein said first charge separating layer comprises poly-(3-hexylthiophene) (“P3HT”) and [6,6]-phenyl-C₇₁butyric acid methyl ester (“PC₇₀BM”), and said second charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and [6,6]-phenyl-C₇₁butyric acid methyl ester (“PC₇₀BM”).

12. A tandem photovoltaic device comprising:
a substantially transparent substrate;
a substantially transparent first electrode on said substrate
a first cell supported on and configured to receive incident electromagnetic radiation in a light propagation path from said substrate, said first cell comprising a first charge separating layer comprising a first semiconducting polymer adapted to create electric charge carriers generated by electromagnetic radiation;
a first titanium oxide layer, wherein said first titanium oxide layer is substantially amorphous and has a general formula of TiOₓ, where X represents a number of 1 to 1.96;
a second cell configured to receive electromagnetic radiation passing out of said first cell in the light propagation path, said second cell comprising a second charge separating layer comprising a second semiconducting polymer adapted to create electric charge carriers generated by electromagnetic radiation;
a second titanium oxide layer adjacent to the second cell, wherein said second titanium oxide layer is substantially amorphous and has a general formula of TiOₓ where X being a number of 1 to 1.96; and
a second electrode.

13. The tandem photovoltaic device of claim 12, wherein said first charge separating layer comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”), and a fullerene derivative, and said second charge separating layer comprises poly-(3-hexylthiophene) (“P3HT”) and a fullerene derivative.

14. The tandem photovoltaic device of claim 13 wherein said fullerene derivative comprises ([6,6]-phenyl-C₆₁-buteric acid methyl ester) (“PCBM”), or [6,6]-phenyl-C₇₁butyric acid methyl ester (“PC₇₀BM”).

15. The tandem photovoltaic device of claim 12 wherein said first charge separating layer comprising poly-(3-hexylthiophene) (“P3HT”) and a fullerene derivative, and said second charge separating layer comprising poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”) and a fullerene derivative.

16. The tandem photovoltaic device of claim 15 wherein said fullerene derivative comprises ([6,6]-phenyl-C₆₁-buteric acid methyl ester) (“PCBM”), or [6,6]-phenyl-C₇₁butyric acid methyl ester (“PC₇₀BM”).

17. A method of preparing a tandem photovoltaic device comprising a first cell comprising a first semiconducting polymer and a first fullerene derivative, a second cell comprising a second semiconducting polymer and a second fullerene derivative, and a first substantially amorphous titanium oxide layer between the first and second cells, the method comprising the steps of:
applying a solution comprising a first semiconducting polymer and a first fullerene derivative to form a first charge separating layer;
applying a solution comprising a titanium oxide precursor to form a first substantially amorphous titanium oxide layer; and
applying a solution comprising a second semiconducting polymer and a second fullerene derivative to form a second separating layer.

18. The method of claim 17 wherein the solution comprising a titanium oxide precursor comprises one or more precursors selected from the group consisting of titanium(IV) butoxide, titanium(IV) chloride, titanium(IV) ethoxide, titanium(IV) methoxide, titanium(IV) propoxide, and Ti(SO₄)₂ in an alcohol solvent.

19. The method of claim 18 wherein the solution comprising a titanium oxide precursor is spin-cast at about 5000 rpm.

20. The method of claim 17 wherein the solution comprising a first semiconducting polymer and a first fullerene derivative comprises poly[2,6-(4,4-bis-(2-ethylhexyl)-4H-cyclopenta[2,1-b;3,4-b1]dithiophene)-alt-4,7-(2,1,3-benzothiadiazole)] (“PCPDTBT”), and ([6,6]-phenyl-C₆₁-buteric acid methyl ester) (“PCBM”) or [6,6]-phenyl-C₇₁butyric acid methyl ester (“PC₇₀BM”).

21. The method of claim 20 wherein the solution comprising a first semiconducting polymer and a first fullerene derivative has PCPDTBT:PCBM or PCPDTBT:PC₇₀BM weight ratio of about 1.0:3.6.

22. The method of claim 20 wherein the solution comprising a first semiconducting polymer and a first fullerene derivative is spin-cast at a speed from about 1500 to about 3500 rpm.

23. The method of claim 17 wherein the solution comprising a second semiconducting polymer and a second fullerene derivative comprises poly-(3-hexylthiophene) (“P3HT”) and [6,6]-phenyl-C₇₁butyric acid methyl ester (“PC₇₀BM”).

24. The method of claim 23 wherein the solution comprising a second semiconducting polymer and a second fullerene derivative has P3HT:PC₇₀BM weight ratio of about 1.0:0.7.

25. The method of claim 23 wherein the solution comprising a second semiconducting polymer and a second fullerene derivative is spin cast at a speed from about 1500 to about 3500 rpm.
